(19) United States
(12) Patent Application Publication
(10) Pub. No.: US 2011/0062720 A1
(43) Pub. Date: Mar. 17, 2011

(54) CONTROL BOX FOR A WIND TURBINE

(75) Inventor: Vilbrandt Reinhard, Rostock (DE)

(73) Assignee: SUZLON ENERGY GMBH, Berlin (DE)

(21) Appl. No.: 12/992,132

(22) PCT Filed: May 11, 2009
(86) PCT No.: PCT/EP09/03325

§ 371 Date: Nov. 11, 2010

(30) Foreign Application Priority Data
May 13, 2008 (DE) 10 2008 023 247.5

(51) Int. Cl. F03D 11/00; H05K 7/20

(52) U.S. Cl. 290/55; 361/690

(57) ABSTRACT

The invention relates to a control box for arranging in a rotor hub of a wind turbine that can be rotated about a rotational axis. Such control boxes receive electrical components such as relays, inverters, sensors and the like, in the inner region thereof, which is defined by a wall, said components being required for the control of sheet displacement systems, also called pitch systems. Spurious particles can find their way into the control box during maintenance or even via air inlets and outlets. Especially dangerous parts are electro-conductive spurious parts that can trigger a short circuit (wires, cable parts, washers, screws etc.) and mechanically relevant bodies that can block ventilators, for example. Wind turbines are also known from prior art, wherein magnets are provided in the control boxes in the rotor hub, and ferro-magnetic spurious particles can thereby be fixed inside the control box. The aim of the invention is to provide a control box for a wind turbine, wherein the fault tolerance of the control box is increased. To this end, according to the features of claim 1, the catching device in the control box has a cavity for receiving spurious particles and an opening for the entrance of spurious particles into the cavity. This causes the spurious particles to be collected by the catching device only by means of gravity and the rotation of the rotor hub. Furthermore, the cavity ensures that the spurious particles caught are held in the catching device.

The invention relates to a control box to be placed inside a rotor hub of a wind turbine, which can be rotated about a rotational axis. Such control boxes house electrical components such as relays, inverters, sensors and the like within the inner space of the box created by a wall, the said components being required for control of blade adjustment systems, also known as pitch systems. The electrical, hydraulic or mechanical pitch systems turn the turbine rotor blades about their longitudinal axis.

Control boxes of the kind mentioned in the introduction are well known in the current state-of-the-art of technology and are used to control pitch control drives in wind turbines and will be referred to as pitch control boxes in the following text. Regulating the temperature of the pitch control boxes is problematic when high power exists in the circuit and high power losses take place within the control box simultaneously while the ambient temperature in rotor hub is high at times, since the heat dissipation through the surface of the control box is itself not sufficient. Based on the heat dissipation of the control box components, the control boxes are cooled passively or actively. A passively cooled control box can be constructed to be hermetically isolated from the environment. In general, an active cooling requires a cooling medium to exchange the heat between the interior of the control box to be cooled and a cooler external environment. Very often this cooling is accomplished by using fans to provide a targeted and forced blast of atmospheric air. In this process the safety class requirements are met by protecting the air inlets and outlets by means of grids and/or filters.

In general, after component assembly and commissioning, the control boxes are opened only for their periodical maintenance. In case of any operational problems, it may be necessary to carry out an unplanned maintenance work.

Spurious particles can find their way into the control box in the course of maintenance or even via air inlets and outlets. In such a case, especially dangerous are the electro-conductive spurious particles that can trigger a short circuit (wires, cable parts, washers, screws etc.) and mechanically relevant bodies that can choke objects like fans, for example. Due to the constant rotation of the entire system, there is a high degree of hazard of component damage caused by the freely moving spurious particles, since these particles are kept in constant motion due to rotation and can certainly lead to problems.

Moreover, in the current state-of-the-art there are wind turbines known wherein magnets are provided in the control boxes in the rotor hub, and as a result ferro-magnetic spurious particles can be held firmly inside the control box. This process, where magnets are used, suffers from the drawback that they can capture exclusively spurious magnetic particles and moreover it has a low capacity to collect such particles. This means that the captured spurious particles significantly reduce the capacity of a capturing device of the state-of-the-art to capture any other particles. For example, any spurious particles of aluminum or austenitic alloys cannot be captured. Such particles, which also are electrically conductive, can lead to short-circuits within the control box or to mechanical destructions.

The objective of the invention is to provide a control box for a wind turbine, whereby the drawbacks of the current state of the art can be avoided.

This should especially enhance the fault tolerance of the control boxes, by restraining the electrical or mechanical defects caused by the spurious particles.

The invention achieves the objective through the features given in the main claim 1, wherein the catching device in the control box has a cavity for receiving spurious particles and an opening for spurious particles to get into the cavity. This causes the spurious particles to be collected by the catching device only by means of gravity and the rotation of the rotor hub. Furthermore, the cavity ensures that the spurious particles caught are held within the catching device.

A first embodiment reveals that the opening is essentially facing the main direction of rotation. To illustrate this it should be stated that such a cross-section or area is considered as the opening which describes the transition between the inner space of the control box and the cavity of the catching device. Firstly this cross section or area should not be designed to be a level surface and it does not correspond to the smallest cross-sectional area between the catching device and the inner space. The orientation of this opening should be defined from the point of its effectiveness in capturing the spurious particles. Now if the opening is facing the main direction of rotation, then during the transition from the inner space of the control box into the cavity of the catching device a spurious particle performs a movement that is essentially a tangential movement against the main direction of rotation with respect to the rotor axis. As such, the driving movement for the capturing process is predominantly the rotation in conjunction with gravity. The direction of rotation intended for the wind turbine's operation is considered as the main direction of rotation.

Another embodiment reveals that the opening is facing a radial direction inward to the rotor axis of the rotor hub. In such a case, the driving force for the capture process is predominantly the gravitational force in conjunction with the rotation. During the transition from inner space into the capturing direction, the spurious particles perform now essentially a radial movement with reference to the rotor axis.

The capturing device can be placed in a radially external, essentially axially located corner of the wall. This placement helps to save space and does not have any negative impact on the placement of the electrical components within the control box. In doing so, the cavity of the capturing device can be advantageously built up using the lateral surfaces of the walls of the control box and a separate limb wall. The opening is provided in the limb wall.

It is also possible to think of essentially placing the capturing device in the inner space of the control box, whereby this arrangement is found to be especially favorable if the capturing device is placed in a corner of the control box.

In an alternative method the capture device can be placed on a lateral surface of the wall. This is especially advantageous, but it is not restricted to the case when the capture device is essentially arranged outside the control box and at least in some cases the opening is created by a cut out in the wall.

One possible layout of the embodiments described above reveals that the capture device includes at least one baffle plate to capture the spurious particle. This serves to capture the spurious particles with ease by enlarging the working surface area of the effective opening. The baffle plate is advantageously placed at the opening itself.

Furthermore, the above-mentioned baffle or an additional baffle can be partially provided within the inner space of the capturing device in such a manner that the captured spurious particles are held securely within the inner space. For example, the cavity can be formed at least partially as a trap or labyrinth by dividing and arranging the baffle. The rotation of the rotor hub causes the spurious particles to get deeper and deeper into the capturing device.

In order to ensure that the collected spurious particles are not lost, such a magnet or an adhesive element can be provided within the cavity of the capturing device, which is suitable for retaining the magnetic and/or also non-magnetic spurious particles in place.

The capturing device also includes an opening for maintenance purposes, which serves to remove the captured spurious particles from the cavity of the capturing unit regularly.

The capturing device can extend over the entire depth of the control box or the capturing device is extended by fitting baffles over the entire depth of the box. In this way, it is ensured that the spurious particles do not circulate in the capturing device and that there are no “dead zones” in which spurious particles could get deposited and thus present an unsafe/dangerous situation.

The invention also covers a wind turbine with a nacelle mounted on a tower while a rotor is fitted on the nacelle so that it can rotate on it, including a rotor hub and at least one rotor blade fitted on it, whereby at least a control box with a capturing device is placed within the hub as described earlier.

The other details of the invention emerge from the drawings in accordance with the descriptive text. In the drawings,

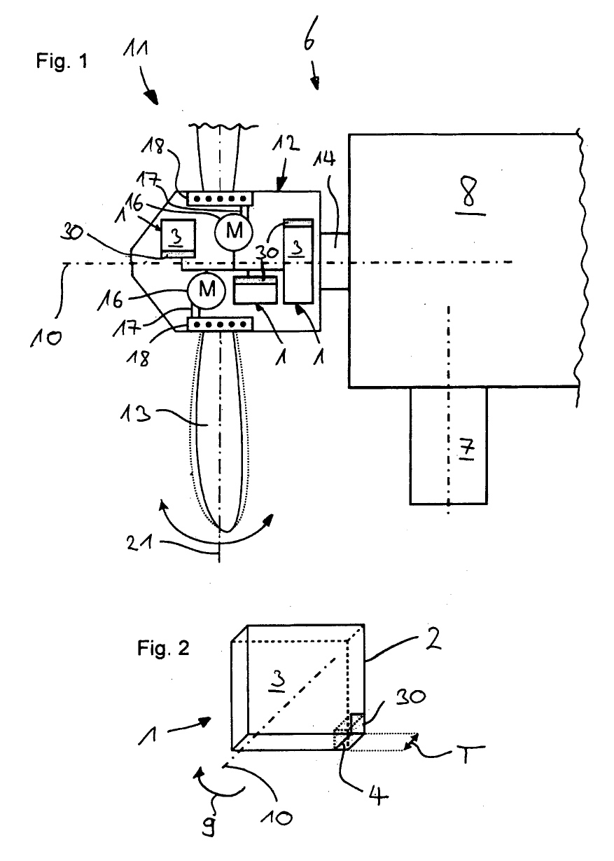

FIG. 1 shows a schematic cross-section through a rotor hub of a wind turbine,

FIG. 2a schematic control box with a capturing device,

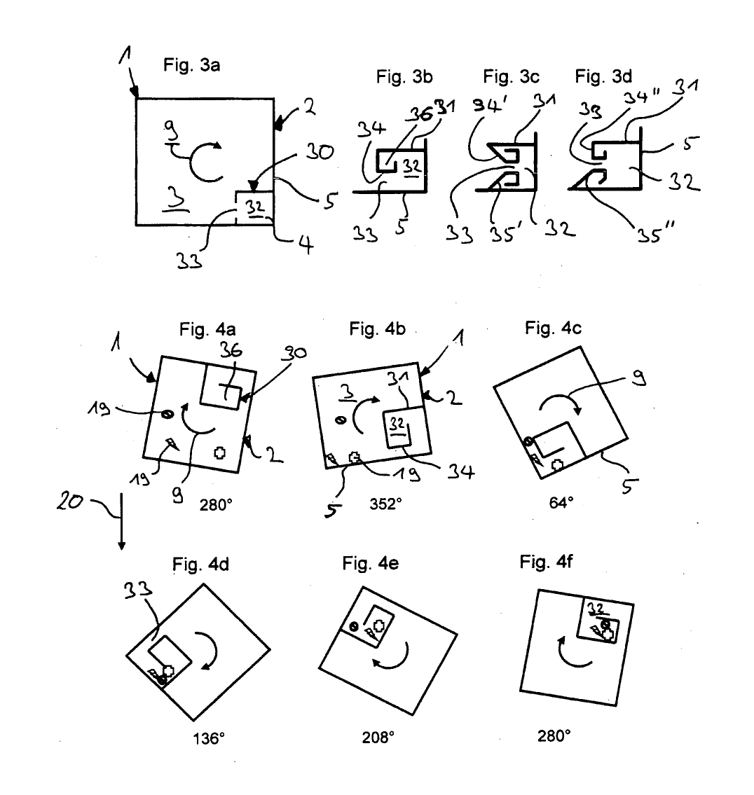

FIG. 3a) shows a schematic control box with three design versions of a capturing device (b-d),

FIG. 4a)-f) the process of capturing the spurious particles in the control box according to FIG. 3a) and b),

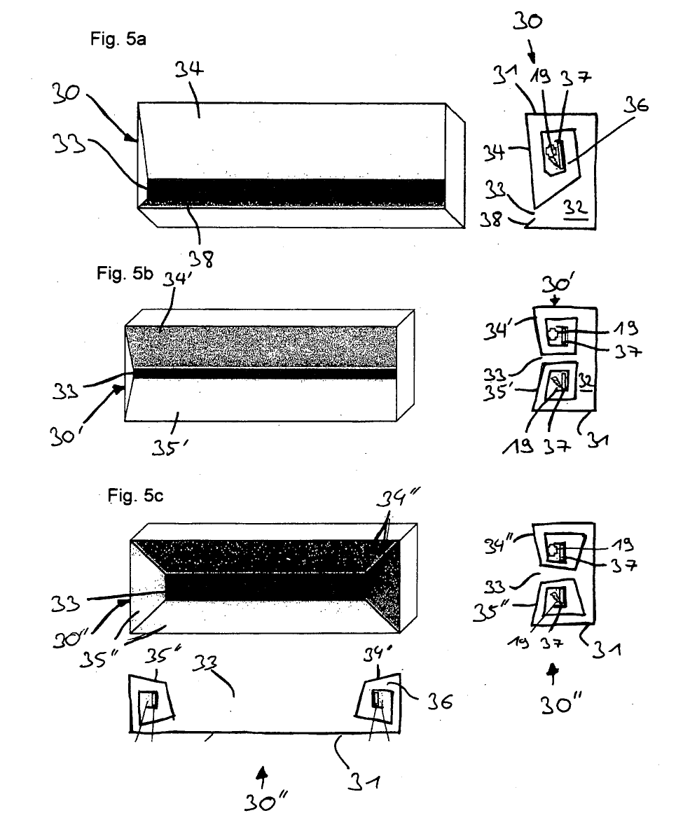

FIG. 5a-c embodiments of a capturing device in various views,

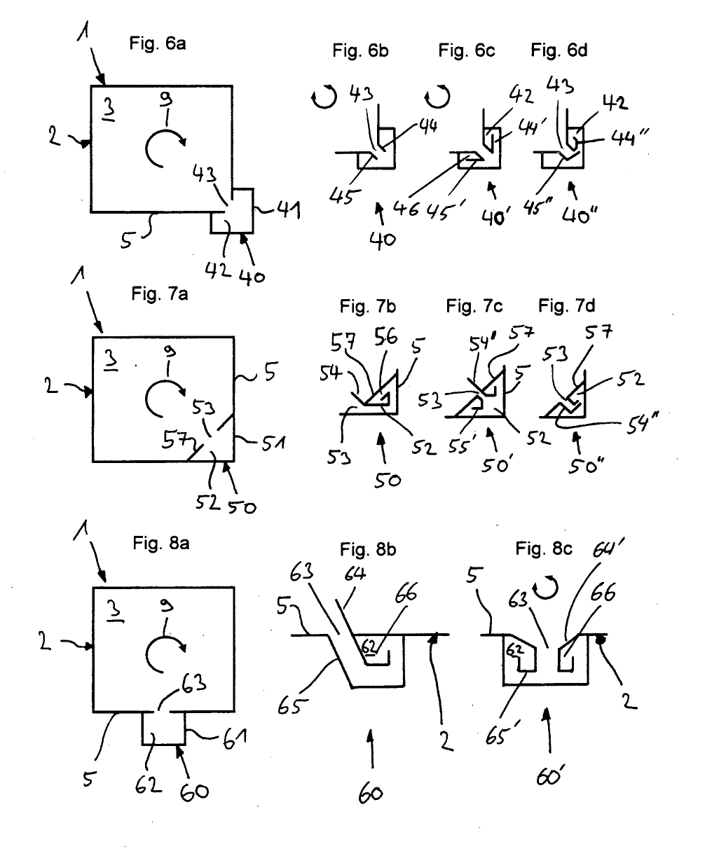

FIG. 6a) a schematic control box with three embodiments of a capturing device (b-d),

FIG. 7a) a schematic control box with three embodiments of a capturing device (b-d), and

FIG. 8a) a schematic control box with two embodiments of a capturing device (b-c).

The view represented in FIG. 1 shows a rotor 11 and the nacelle 8 of a wind turbine 6. The rotor 11 includes the rotor hub 12, rotor blades 13 and a rotor shaft 14, which is mounted on a bearing to be able to rotate about the rotor axis of the nacelle 8. The nacelle 8 is mounted on a tower 7, so that it can be rotated for wind tracking. A rotor hub 12 with adjustable rotor blades 13 is shown in the figure. The rotor blades 13 are mounted in a blade bearing 18, so that they can be rotated and adjusted about the rotor blade axis 21.

Within the rotor hub 12, each of the rotor blades 13 can be driven via an electric motor 16 and a gear box 17 (as shown in the example) to enable them to rotate. Alternatively, one drive can be used for several rotor blades or several drives for one rotor blade. These alternatives are not shown. Likewise, it is also possible to use other types of drives (such as hydraulic systems, for instance) rather than a combination of motor and gear box.

According to FIG. 1 the electrical motors 16 are controlled from a main control box 1. Optionally, several distributed control boxes too can be used instead of a single main control box 1. In an emergency due to voltage drop, the motors 16 are supplied through an electrical energy storage device and this allows the rotor blades 13 to be positioned reliably. Various accumulator types and condensers are known to be used as electrical energy storage devices. All control boxes 1 for components, such as control devices and electrical energy storage unit for back-up systems, are equipped with capturing devices 30, 40, 50 or 60. These devices absorb all the spurious particles 19 that are found within the control box and retain them. In this manner, the danger of an interruption or a defect triggered by the conductive spurious particles 19 or mechanical choking caused by spurious particles 19 is minimized.

A schematic representation of the control box 1 fitted with a capturing device 30, 40, 50 or 60 as per the invention is depicted in FIG. 2. The capturing device 30, 40, 50 or 60 consists of a box, which produces a cavity 32, 42, 52 or 62 and has an opening 33, 43, 53 or 63 and extends over the entire depth of the control box. The capturing device 30, 40, 50 or 60 is formed according to the design geometries and their shapes shown in FIG. 3, 5, 6, 7 or FIG. 8, whereby their size is proportional to the size of the control box.

In FIG. 3a, a control box 1 is shown as per FIG. 2, whereby FIG. 3b to FIG. 3d reveals three usable designs of the capturing device 30. Each of the capturing devices 30 can be mounted in an axial corner 9 in the inner space 3 of the control box 1. The capturing unit 30, as per FIG. 3b, has a wall 31 that creates the cavity 32 and an opening 33, whereby the opening 33 faces the main direction of rotation 9. At the opening 33 a baffle 34 is provided, which produces a labyrinth 36 within the capturing device 30.

As an example, the process of capturing the spurious particles 19 by the capturing device as per FIG. 3a can be illustrated with the help of FIG. 4. The same principle holds good for the other embodiments of capturing devices 40, 50, 60 too. In FIG. 4a, spurious particles 19 are found in a free state in the inner space 3 of the control box 1 and therefore they are in a position to cause destructions within the control box 1. The gravitational force 20 (represented here by arrow 20) causes the spurious particles 19 to move towards the bottom and to deposit on a lateral surface 5 of the wall 2 (FIG. 4b). If the control box 1 rotates further (FIG. 4c), then, driven by gravity, the spurious particles 19 slip through the opening 33 of the capturing device 30.

The spiral shaped baffle 34 conveys the spurious particles 19 deeper into the labyrinth 36 (FIG. 4d, e). In FIG. 4f, the control box 1 is found in the initial position in accordance with FIG. 4a. In such case, the spurious particles 19 are present in the cavity of the capturing device 30, as a result of the rotation, the shape of the capturing device 30 and that of the baffles 34. Moreover, the spurious particles 19 are prevented from going back to the inner space of the control box 1.

The capturing devices 30, as per FIG. 3c and FIG. 3d, have baffles 34, 35, 34′, 35′ designed to have another shape, but the principle of capture of the spurious particles 19 is maintained as same. The twisted baffles 34, 34′, 35 allow an improved process of collecting the particles, whereby the second baffle 35, 35′ also guarantees holding the captured spurious particles 19 in place, if the rotor hub 12 should rotate against the main direction of rotation 9.

FIG. 5a shows an improved embodiment of the capturing device 30 according to FIG. 3b. The opening 33 is placed in the main direction of rotation 9 of the control box 1 or that of the rotor hub 12 and thus it accepts the free moving spurious particles 19. In this process the spurious particles 19 are guided to the opening 33 by a baffle 34. The baffle 34 is folded inwards to the interior in a spiral shape, so that the spurious particles 19 are prevented from going out. If necessary, an adhesive element 37, preferably a permanent magnet or any other temperature and aging resistant adhesive element, can ensure, in addition, that the spurious particles 19 are brought to a form and remain intact until maintenance. Additionally, the lip edge 38 prevents the captured spurious particles 19 from escaping from the capturing device 30.

FIG. 5b and FIG. 5c show other embodiments of the capturing device 30 in accordance with FIG. 3c or FIG. 3d. Here the openings 33 are placed in the centre. Over and above this, in FIG. 5c, not only the upper and lower baffles 34, 34′, 35′, 34″ 35″ are folded inwards in a spiral shape, but also baffles 34, 34′, 35′, 34″, 35′, which are formed inwards in spiral shape, are placed on the right and left of the opening 33.

The design shapes of the capturing devices 40 from FIG. 6 are placed at a corner 4, outside of the control box 1. This enables the control box 1 to accommodate more components. A cut out in a side surface 5 of wall 2 of control box 1 serves as the opening between the inner space 3 of the control box 1 in the cavity 42 of the capturing device 40. The capturing devices 30, as per FIG. 6a and FIG. 5b, are in a position to collect the spurious particles 19 independent of the main direction of rotation 9 from the inner space 3 of the box. The capturing device 30 in FIG. 6c and FIG. 6d shows a labyrinth-like feature of the baffles 45′ 44′, 44″.

FIG. 7 shows a control box 1 in which a embodiment of the capturing device 50 is placed in the corner 4 according to the three design arrangements (FIGS. 7b - 7d). Unlike the previous cases, the cavity 53 of capturing device 50 is created by two or three lateral surfaces 5 of the wall 2 of the control box 1 and by a limb wall 57. In this way, it is possible to produce the capturing device 50 with advantages and to save space. The capturing devices 50 as per FIG. 7b and c show a baffle at the opening 53, which firstly is projecting into the interior 3 of the control box 1, and as such serves to capture the spurious particles better. Secondly, the baffle 54, 54′ produces a labyrinth-like construction in cavity 52. As a result, the spurious particles 19 are held firmly within the capturing device 1.

Similar to the design in FIG. 6, the capturing devices 60 as per FIG. 8b and c are fitted outside the control box 1, however on a lateral surface 5 of the wall 2. The capturing device 60, as per FIG. 8c, is in a position to collect the spurious particles 19 from the inner space 3 independent of the direction of rotation 9.

The application of the combination of features depicted in the embodiment examples should not be restricted only to the invention itself; rather it should also be possible to combine the features of different versions with one another.

### LIST OF REFERENCES

1 Control box
2 Wall
3 Inner space
4 Corner
5 Lateral surface
6 Wind turbine
7 Tower
8 Nacelle
9 Main direction of rotation
10 Rotor axis
11 Rotor
12 Rotor hub
13 Rotor plate
14 Rotor shaft
15 Direction of rotation
16 Electrical motor
17 Gear box
18 Blade bearing
19 Spurious particles
20 Gravity
21 Rotor blade axis
30 Capturing device
31 Wall
32 Cavity
33 Opening
34 Baffle
35 Baffle
36 Labyrinth
37 Adhesive element
38 Lip
40 Capturing device
41 Wall
42 Cavity
43 Opening
44 Baffle
45 Baffle
46 Labyrinth
50 Capturing device
51 Wall
52 Cavity
53 Opening
54 Baffle
55 Baffle
56 Labyrinth
57 Limb wall
60 Capturing device
61 Wall
62 Cavity
63 Opening
64 Baffle
65 Baffle
66 Labyrinth
T Depth

1. Control box (1) to be placed in a rotor hub (12) of a wind turbine (6),
the hub being rotatable about a rotor axis (10),
with a wall (2) creating an inner space (3) to accommodate electrical components,
and with a capturing device (30, 40, 50, 60) to capture spurious particles (19), wherein the capturing device (30, 40, 50, 60) has a cavity (32, 42, 52, 62) to accept spurious particles (19) and an opening (33, 43, 53, 63) for the spurious particles (19) to enter into the cavity (32, 42, 52, 62).

2. Control box (1) according to claim 1 wherein the opening (33, 53, 63) essentially faces a main direction of rotation (9) of the rotor hub (12).

3. Control box (1) according to claim 1 wherein the opening (43, 53, 63) essentially faces radially inwards to the rotor axis (10).

4. Control box (1) according to claim 1, wherein the capturing device (30, 40, 50) is arranged on a radially external, essentially on an axial running corner (4) of the wall (2).

5. Control box (1) according to claim 4, wherein the capturing device (50) is formed by lateral surfaces (5) of the wall (2) and by a limb wall (57), whereby the limb wall (57) has the opening (53).

6. Control box (1) according to claim 1, wherein the capturing device (60) is placed on a lateral surface (5) of the wall (2).

7. Control box (1) according to claim 4, wherein the capturing device (30, 50) is essentially arranged in the inner space (3) of the control box (1).

8. Control box (1) according to claim 4, wherein the capturing device (40, 60) is arranged essentially outside the control box (1) and the opening (43, 63) is formed at least partially by an opening in the wall (2).

9. Control box (1) according to claim 1, wherein the capturing device (30, 40, 50, 60) includes one baffle plate (34, 34′, 34″, 35′ 35″, 44, 44′ 44″, 45, 45′, 45″, 54, 54′, 54″ 55′ 55″, 64, 64′, 65, 65′) for capturing the spurious particles (19).

10. Control box (1) according to claim 9, wherein the baffle plate (34, 34′, 34″ 35′ 35″, 44, 44′ 44″, 45, 45′, 45″, 54, 54′, 54″ 55′ 55″, 64, 64′, 65, 65′) is placed at the opening (33, 43, 53, 63).

11. Control box (1) according to claim 10, wherein a baffle plate (34, 34′, 34″ 35′, 35″ 44′, 44″, 45′, 54, 54′ 55′, 64, 64′, 65, 65′) is provided partially within the cavity (32, 42, 52, 62) of the capturing device (30, 40, 50, 60) in such a way that the captured spurious particles (19) are retained safely within the cavity (32, 42, 52, 62), especially by the cavity (32, 42, 52, 62) formed at least partially by means of the baffle plate (34, 34′, 34″ 35′ 35″ 44′, 44″, 45′, 54, 54′, 55′, 64, 64′, 65, 65′) as a labyrinth (36, 46, 56, 66) or as a trap.

12. Control box (1) according to claim 1, wherein the capturing device (30, 40, 50, 60) has an opening for maintenance, through which the captured spurious particles (19) can be removed from the capturing device (30, 40, 50,60).

13. Control box (1) according to claim 1, wherein the capturing device (30, 40, 50, 60) includes a magnet or an adhesive element (37).

14. Control box (1) according to claim 1, wherein the capturing device (30, 40, 50, 60) extends essentially over the entire depth (T) of the control box (1).

15. Wind turbine (6) with a nacelle (8) arranged on a tower (7), with a rotor (11) that is mounted rotatable to on the said nacelle (8), comprising a rotor hub (12) and one rotor blade (13) arranged on the said rotor hub (12), wherein at least-one control box (1) according to claim 1 is provided in the rotor hub (12).
